(19) United States
(12) Patent Application Publication
(10) Pub. No.: US 2024/0203735 A1
(43) Pub. Date: Jun. 20, 2024

(54) METHOD FOR PRODUCING DOPED TRANSISTOR SOURCE AND DRAIN

(71) Applicant: COMMISSARIAT A L'ENERGIE ATOMIQUE ET AUX ENERGIES ALTERNATIVES, Paris (FR)

(72) Inventors: Shay REBOH, Grenoble Cedex 09 (FR); Pablo ACOSTA ALBA, Grenoble Cedex 09 (FR); Frédéric MILESI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/543,987

(22) Filed: Dec. 18, 2023

(30) Foreign Application Priority Data
Dec. 20, 2022 (FR) 22 13950

(51) Int. Cl. H01L 21/02; H01L 29/66

(52) U.S. Cl. CPC H01L 21/02675; H01L 29/66772

(57) ABSTRACT

A method for producing a transistor comprising:

providing on a support provided with a surface semiconductor layer and resting on an insulating layer: a gate block, insulating spacers on either side of this gate block, and so-called raised semiconductor regions,

making amorphous the raised semiconductor regions and the portions of the superficial semiconductor layer located under these raised semiconductor regions and reaching the insulating layer,

doping the raised semiconductor regions and said portions,

carrying out a laser heat annealing by means of one or more laser pulses so as to produce a recrystallisation of said raised regions and of said portions while carrying out an activation of dopants in said regions and said portions.

### TECHNICAL FIELD AND PRIOR ART

The present application relates to the field of methods for manufacturing transistors, and more particularly to that for forming improved doping source and drain semiconductor regions.

In the methods for manufacturing transistors, the doping of source and drain regions poses certain difficulties. Firstly, the activation of dopants generally requires a high temperature.

Furthermore, it is generally sought to extend the doped regions by performing a doping under insulating spacers in order to create so-called “extension” areas of the source and of the drain.

With regards to the thermal budget problem, a solution consists in activating the dopants at low temperature during a Solid Phase Epitaxial Regrowth (SPER) phase of semiconductor areas made amorphous and containing dopants. The SPER technique encourages the recrystallisation of a solid with a reduced thermal barrier. This technique requires the presence of a crystalline thickness that is used as a seed for the recrystallisation.

With such a technique, amorphous silicon (a-Si) may for example grow into a crystal from crystal seeds at low temperatures, for example in the order of 500° C. This SPER temperature may even be further reduced with the presence of dopants.

Thus, a method for producing doped source and drain regions consists in making amorphous the upper areas of semiconductor regions and in keeping an underlying crystalline part to be able to activate the SPER recrystallisation. Dopants are then implanted at least in the amorphous region. During the recrystallisation method, an activation of the dopants is implemented.

One drawback of this method is that a non-doped underlying crystalline part is kept, which may induce a contact resistance between the channel and the source drain regions all the more penalising because the thicknesses used are low.

Another drawback of such a method, is that for the very thin semiconductor layers, for example less than 10 nm, it is difficult to make amorphous the upper part of these layers while keeping in the lower portion a crystalline seed of sufficient thickness.

Moreover, the kept lower crystalline part is not generally uniform in terms of thickness, which may lead to resistance variations, in particular significant access resistances from one transistor to the other over the entire surface of the support whereon these transistors are produced.

The problem of finding a new improved method for manufacturing transistors arises in relation to the aforementioned drawbacks.

### DISCLOSURE OF THE INVENTION

One aim of the invention is to propose a method for producing a microelectronic device for producing at least one transistor provided with source and drain regions with improved doping, in particular over their entire thickness, while limiting the thermal budget used.

One embodiment of the present invention provides a method for producing a transistor comprising the following steps of:
providing on a support provided with a surface semiconductor layer and resting on an insulating layer: at least one transistor gate block arranged on the surface layer, insulating spacers on either side of this gate block, and so-called raised semiconductor regions resting on the surface semiconductor layer on either side of this gate block and insulating spacers, then,
making amorphous the raised semiconductor regions and the portions of the surface semiconductor layer located under these raised semiconductor regions over their entire thickness and so as to reach the insulating layer,
doping the raised semiconductor regions and the portions of the surface semiconductor layer,
then,
carrying out at least one laser thermal annealing by means of one or more laser pulses so as to perform a recrystallisation of the raised regions and of the portions of the surface semiconductor layer while carrying out an activation of dopants in these regions and these portions.

Here a complete amorphisation is performed over the entire thickness of the semiconductor regions and portions of the surface semiconductor layer in order to be able to carry out a doping over the entire thickness of the semiconductor regions and portions of the surface semiconductor layer. The doping and the amorphisation may be performed concomitantly by implantation.

Laser annealing has the advantage of making it possible to activate dopants without necessarily having to have preserved in advance a crystalline thickness and while limiting the thermal budget used.

In particular, a nanosecond laser annealing is used with one or more pulses of duration less than 1 μs.

Laser thermal annealing may thus be carried out using a laser with a wavelength between 200 nm and 600 nm and advantageously between 200 and 400, by emitting one or more successive laser pulses, of pulse duration less than a microsecond and preferably between 1 ns and 1,000 ns, advantageously between 20 ns and 300 ns.

Laser thermal annealing is preferably carried out in a so-called “explosive” recrystallisation mode wherein the raised semiconductor regions and the portions are transformed into polycrystalline material.

The person skilled in the art would tend to want to produce monocrystalline source and drain semiconductor regions but the inventors experimentally noted, surprisingly, that raised semiconductor regions and portions recrystallised according to such a mode make it possible to produce sources and drains having a low resistance.

According to one embodiment, the step of making amorphous the raised semiconductor regions and the portions may be carried out by ion implantation using an ion beam inclined in relation to a normal to a main plane of the support, so as to perform an amorphisation of areas of the surface layer that extend under the spacers. This contributes to an improved doping of the areas extending under the spacers.

Advantageously, the method may further comprise steps of:
forming the gate block,
forming spacers on either side of the gate block,
forming the raised semiconductor regions on either side of the spacers.

The method may then further comprise after forming the gate block and before forming the spacers:
doping so-called extension areas of the surface semiconductor layer located on either side of the gate block, the spacers being formed facing the extension areas.

Advantageously, doping the extension areas in the surface semiconductor layer on either side of the gate block comprises steps of:
making amorphous and doping an upper part of the surface layer while keeping a crystalline lower layer of the surface layer in contact with the insulating layer,
carrying out an annealing so as to recrystallise the upper part of the surface layer.

According to a possible implementation, after forming the insulating spacers and before amorphising the raised semiconductor regions and portions of the surface semiconductor layer located under these semiconductor regions:
forming by epitaxy the raised semiconductor regions on the recrystallised upper part of the surface layer.

According to an advantageous implementation, after laser thermal annealing, the method may comprise a step of forming regions based on metal material or semiconductor material compounds in the raised semiconductor regions.

According to a first possibility, before the laser thermal annealing at least one metal material layer can be deposited so as to cover the raised semiconductor regions, the laser thermal annealing then being adapted to form the regions based on metal material and semiconductor material compounds in the raised semiconductor regions.

According to a second possibility, after the laser thermal annealing, the method may comprise steps of:
making amorphous the upper parts of the raised semiconductor regions, then
depositing at least one metal material layer so as to cover the raised semiconductor regions, and carry out an annealing to form regions based on metal material and semiconductor material compounds in the upper parts.

According to a particular implementation of the method, said portions of the surface semiconductor layer located under the raised semiconductor regions correspond to parts of the surface semiconductor layer not covered by the spacers and the gate block and that extend over the entire thickness of the surface semiconductor layer.

According to a possible implementation of the method, the step of making amorphous the raised semiconductor regions and the portions of the surface semiconductor layer being carried out so as not to keep any crystalline seed in the surface layer outside of an area facing the gate block.

The support of the surface semiconductor layer may be a substrate of semiconductor on insulator type such as a SOI (Silicon On Insulator) substrate or a support provided with one or more components of a first level of components formed in an underlying semiconductor layer.

Thus, the method lends itself more particularly to producing 3D devices or circuits provided with a plurality of superposed semiconductor layers and with a plurality of levels of components produced in these layers. In particular, the fact of being able to use a reduced thermal budget to form the raised source and drain regions makes it particularly compatible with the implementation of 3D devices or circuits, that is to say produced on a plurality of levels of components formed in distinct semiconductor layers.

### BRIEF DESCRIPTION OF THE DRAWINGS

The present invention will be better understood in light of the following description and the appended drawings wherein:

FIGS. 1A, 1B, 1C, 1D and 1E illustrate a method for producing a transistor with source and drain semiconductor regions doped over their entire thickness.

FIG. 2 illustrates an alternative embodiment wherein semiconductor and metal alloy regions are further formed in the doped semiconductor regions.

FIG. 3 illustrates an alternative embodiment wherein laser annealing is carried out after doping the semiconductor regions then a step of depositing metal material in order to combine an activation of dopants with a siliconisation of the source and drain semiconductor regions.

FIGS. 4A, 4B, 4C, 4D, 4E and 4F illustrate another particular example of embodiment for which a doping of the extension areas is performed before forming and doping the raised parts of the source and drain regions.

FIGS. 5A, 5B, 5C, 5D, 5E, 5F, 5G, 5h and 5I illustrate another particular example of embodiment for which a doping of areas of a surface semiconductor layer is performed before forming the raised parts of the source and drain regions and making amorphous over their entire thickness these areas and these raised parts.

FIG. 6 illustrates a particular example of embodiment wherein the support based on which the method is performed is already provided with a level of components formed in an underlying semiconductor layer.

Furthermore, in the description hereafter, terms that depend on the orientation of the structure such as “front”, “upper”, “back”, “lower”, “lateral”, are applied by considering that the structure is orientated in the manner illustrated in the figures.

### DETAILED DISCLOSURE OF PARTICULAR EMBODIMENTS

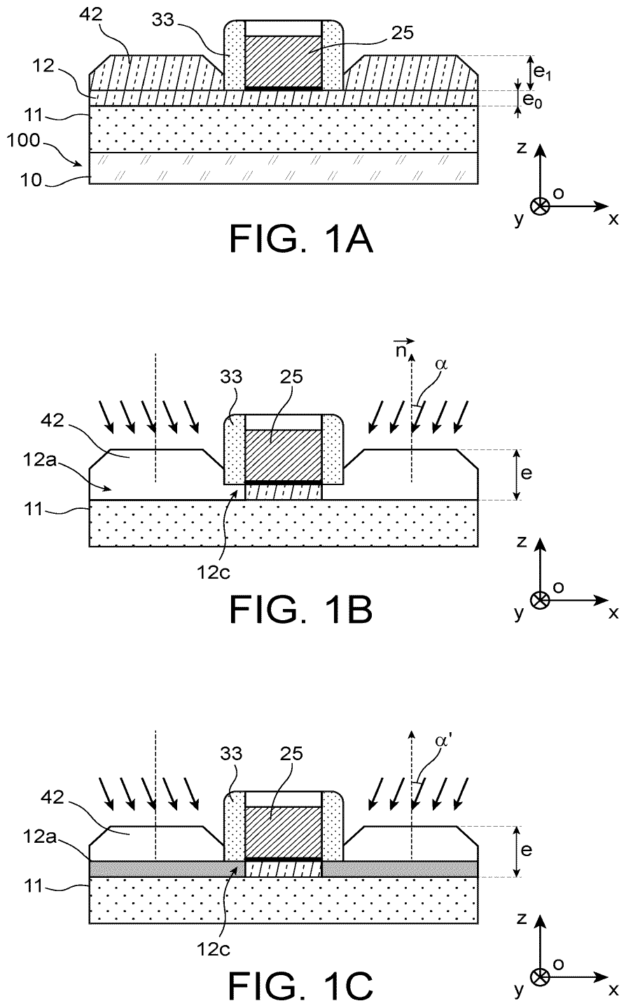

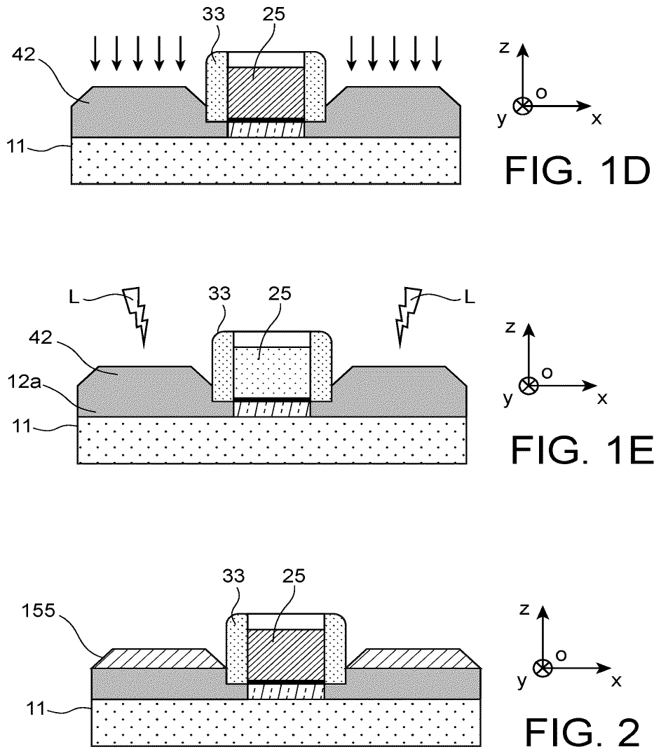

A possible starting structure for producing a method according to the invention and implemented for manufacturing at least one transistor is given in FIG. 1A. This structure comprises a support 100 provided with an insulating layer 11, for example made of SiO₂, and commonly called BOX (buried-oxide), the insulating layer 11 itself being covered with a surface semiconductor layer 12 wherein one or more transistors are intended to be formed.

The surface semiconductor layer 12, for example made of silicon, is provided with a thickness that may be for example between 5 nm and 100 nm, advantageously between 5 and 30 nm.

The insulating layer 11 for its part may be provided with a thickness for example between 15 nm and 200 nm.

A particular example of embodiment provides an insulating layer 11 of silicon oxide of 145 nm and a surface layer 12 and a silicon layer in the order of 23 nm or 30 nm of thickness.

The support 100 whereon the insulating layer 11 is resting, is in this particular example of embodiment, a support semiconductor layer 10 of a substrate of semiconductor on insulator type such as a SOI (Silicon On Insulator).

The transistor(s) formed may be provided in FDSOI (“Fully Depleted Silicon On Insulator”) technology.

In the example of embodiment illustrated, the structure is provided with a transistor gate block 25. This block 25 is formed here of a gate dielectric region 21, for example made of SiO₂ or of HfO₂ overmounted by a gate region 22 formed of one or more gate material layers for example based on polysilicon or TiN or W or on a stack of at least a plurality of these materials. Spacers 33 are produced on either side of the gate block 25. These spacers 33 may be for example based on SiN or SiBCN or SiOCN.

So-called “raised” semiconductor regions 42, for example made of silicon, are here formed on either side of the gate block 25, typically by epitaxy.

Subsequently, an amorphisation of the semiconductor regions 42 and of the portions 12a of the surface semiconductor layer 12 is performed. This amorphisation is typically implemented by means of at least one ion implantation.

In the example illustrated in FIG. 1B, an inclined amorphisation implantation is performed. Thus, uses an implantation beam producing a non-zero a angle in relation to a normal n to a main plane of the support 100 (i.e. a plane of the support parallel to the plane [O; x; y] of an orthogonal coordinate [O; x; y; z] given in FIG. 1B). Here, preferably the amorphisation implantation(s) are performed after having formed insulating spacers 33 on either side of the gate block 25.

Here, the amorphisation is advantageously carried out over the entire thickness e (e=e₀+e₁) of the semiconductor regions 42 and of the semiconductor layer 12. Thus, the raised semiconductor regions 42 of thickness e₁ are made entirely amorphous.

The portions 12a of the surface semiconductor layer 12 e₀ are also made amorphous over their entire thickness e₀ and thus reach the insulating layer 11 so as to be in contact with the latter.

Due to the inclined beam implantation, the portions 12a made amorphous of the surface semiconductor layer may include areas 12c that extend under the spacers 33.

In order to perform the amorphisation, an implantation of a neutral and non-doping species, for example of Silicon or Germanium ions, with dose conditions, of energy determined by experimental simulation and verification by TEM (transmission electron microscopy) imaging may be implemented. Simulation tools based on a Monte-Carlo method, in particular of the TRIM (TRansport of Ions in Matter), and/or KMC (“kinetic Monte Carlo”) type.

For example, an implantation of Ge ions with a dose of 6×10¹⁴ ions*cm⁻² according to an energy of 9 keV may make it possible to obtain an amorphous thickness in the order of 15 nm of silicon.

In the case particularly of an amorphisation performed using a neutral species, it is subsequently possible (FIG. 1C) to perform a doping of the parts of the semiconductor layer 12 on either side of the gate block 25 and in particular a doping of extension areas located on either side of the gate facing the insulating spacers 33.

Thus, in the example of embodiment illustrated in FIG. 1C, a doping implantation is carried out using an inclined beam and producing a non-zero angle α′ in relation to a normal n to a main plane of the support 100 in order to perform a doping of the portions 12a made amorphous and of the areas 12c located under the insulating spacers 33.

According to a possible implementation, this doping implantation may be envisaged at low dose, that is to say typically below 1.0×10¹⁴ ions*cm⁻² and advantageously below 5.0×10₁₃ ions*cm⁻².

Subsequently, another doping implantation can be carried out (FIG. 1D) this time at higher dose and using a straight beam that is to say parallel or substantially parallel to a normal n to a main plane of the support 100. Doping of the raised regions 42 and made amorphous is then carried out in particular over their entire thickness.

A doping method comprising an inclined and low dose implantation and another straight and high dose implantation (i.e. parallel to a normal to the substrate) may make it possible to avoid performing a doping too close to an area 121 of the semiconductor layer wherein the channel of the transistors is provided. However, alternatively it can be envisaged to combine these two doping steps.

The step(s) of doping on raised semiconductor regions 42 and portions 12a made amorphous over their entire thickness here enables a doping of the regions 42 and portions 12a over their entire thickness.

Laser L annealing is subsequently carried out (FIG. 1E) so as to perform a recrystallisation of the raised semiconductor regions 42 and of the portions 12a of the surface semiconductor layer 12.

A laser treatment makes it possible to very rapidly heat to high temperatures and to rapidly cool the structure, once the exposure to the laser has stopped. The laser recrystallisation may in particular be implemented by subjecting the regions 42 and the portions 12a to one or even more pulses of a laser L, and in particular of a so-called “nanosecond” laser, beam that is to say with a pulse duration typically less than 1 microsecond.

The use of a laser operating in pulse mode makes it possible to limit the thermal budget, while avoiding too high an overall temperature rise of the rest of the structure.

The wavelength of the laser L, the pulse duration of the laser beam and preferably the energy density of the laser beam are chosen depending particularly on the thickness of the surface layer and of the raised regions 42 as well as on the reflectivity of the underlying layers.

Preferably, the pulse duration and the energy density of the laser are chosen so as to carry out a recrystallisation in a so-called “explosive recrystallisation” mode. Such a mode is described for example in the document “Melting Temperature and Explosive Crystallization of Amorphous Silicon during Pulsed Laser Irradiation”, Thompson et al., 1984. Laser thermal annealing is in particular envisaged so as to transform these portions 12a and regions 42 into polycrystalline material, in particular into polysilicon when these portions 12a and regions 42 are made of amorphous silicon.

Typically, it is envisaged to use a laser of wavelength between 200 nm and 600 nm, and in particular between 200 nm and 400 nm.

The duration of the, or of each, pulse of the laser beam may be for example between 1 ns and 1,000 ns, and preferably between 10 ns and 500 ns.

At a given wavelength of the laser, the energy density of the laser beam chosen depends on the reflectivity of the stack.

According to a particular example of embodiment with a silicon layer 12 in the order of 12 nm and raised regions 42 made of silicon with maximum thickness between 20 and 30 nm, it is possible to envisage an energy density between 0.5 and 1.0 J/cm².

This range may be expanded and/or modified depending on the stack produced of the surface layer 12 and of the regions 42 and of the dopant doses used. The Person Skilled in the Art may use simulation tools for example such as COMSOL Multiphysics or LIAB (LASSE Innovation Application Booster) and physical characterisation tools using imaging for example TEM (transmission electron microscopy) and ellipsometer to determine the exact conditions depending on the stack chosen.

As the portions 12a and the raised regions 42 are doped, the laser thermal treatment concomitantly makes it possible to perform an activation of dopants.

The explosive recrystallisation mode with a nanosecond laser has the advantage of being able to be implemented, even when the regions to be recrystallised are completely amorphous and when, as in the example of embodiment described above, an underlying crystalline layer is not provided as a starting area for a recrystallisation front.

Apart from the aforementioned advantages, implementing a recrystallisation with a nanosecond laser operating in pulse mode encourages keeping the form of the raised semiconductor regions 42.

In order to help preserve the form of the raised semiconductor regions 42 during the activation annealing, it is possible, according to an optional particular embodiment, to envisage before the exposure to the nanosecond laser, covering these regions with an encapsulation layer transparent to the laser radiation used. Such an encapsulation layer is then used as a mould and makes it possible to preserve the form of the raised semiconductor regions 42 in spite of a possible partial melting of an upper part of these regions.

According to a possible implementation, after recrystallising the portions 12a and raised regions 42, it is subsequently possible to form semiconductor and metal alloy areas 155 in the raised semiconductor regions 42 (FIG. 2).

Preferably, this step is performed at a temperature less than 600° C. and advantageously less than 500° C. For this, a sputtering method for example can be used to deposit a metal material then carry out a thermal treatment. A particular example of method consists, when the raised regions 42 are made of silicon, in performing a siliconisation by forming areas 155 of a metal-silicon alloy, for example NiPtSi.

As a variant of the example of method described above, it is possible to combine the amorphisation and doping steps by implementing an amorphisation implantation using a doping species.

For example, an implantation according to an adequate implantation energy and with arsenic or phosphorous may be implemented to perform an N-type doping concomitantly with an amorphisation of the raised regions 42 and of the surface semiconductor layer 12. Another example of embodiment envisages an implantation of BF2 in order to perform an amorphisation and a concomitant P-type doping. For a phosphorous implantation the following conditions may for example be used: dose=5^{E}14 at/cm². Energy=10 keV, for performing an amorphisation of approximately 16 nm. For similar implantation energies and doses, with BF2 ions an amorphisation depth in the order of 11 nm may be obtained.

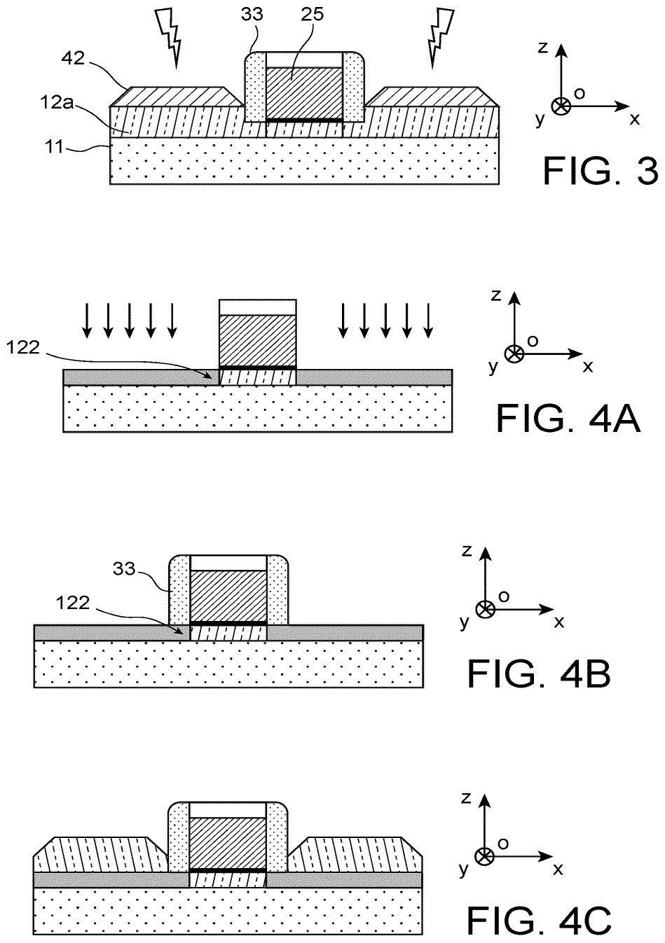

According to an alternative embodiment illustrated in FIG. 3, laser annealing such as described above and for recrystallising the regions 42 and portions 12a may be carried out after a step of depositing metal in view of forming semiconductor and metal alloy areas 155. In this case, it is possible to combine at least one part of the recrystallisation annealing and to produce semiconductor and metal alloy areas. This may also make it possible to form semiconductor and metal alloy areas from a material without crystalline defects.

According to another alternative embodiment, the doping of the surface semiconductor layer 12 and of the raised semiconductor regions may be performed in a plurality of steps.

In particular, it may be envisaged to dope the extension areas after forming the gate block 25 but before producing the spacers.

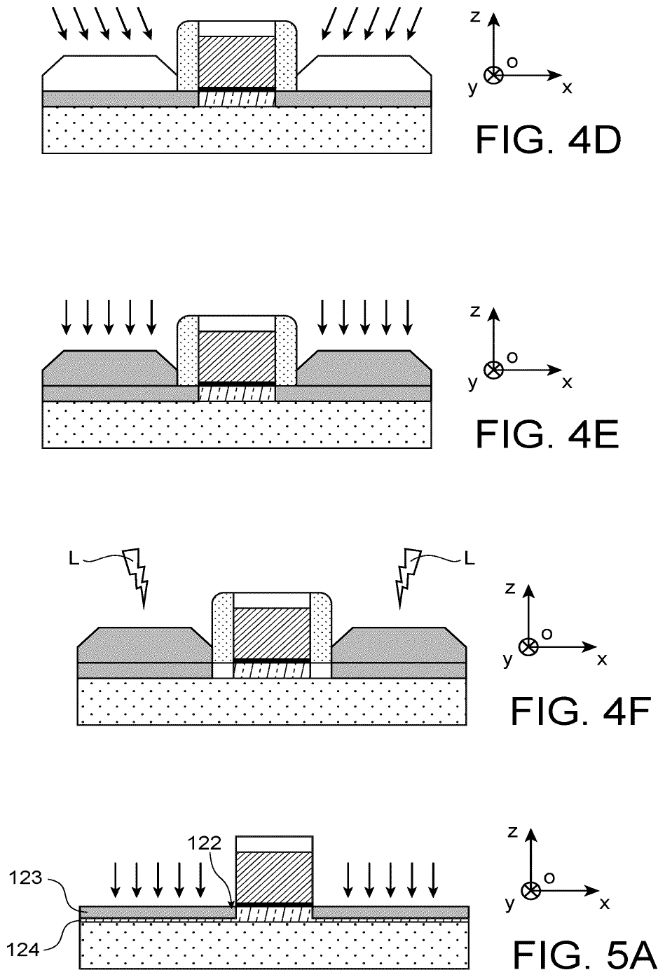

Thus, in the example of embodiment illustrated in FIG. 4A, for this at least one first doping implantation is carried out preferably with a beam not inclined in relation to a normal to the main plane of the support.

Then (FIG. 4B), the spacers 33 are formed. This may be performed for example by depositing an insulating layer, for example made of silicon nitride, then etching, for example dry etching using a plasma. Before proceeding to this etching typically a photolithographic step is performed in order to protect the areas that it is not desired to etch.

Subsequently (FIG. 4C), the raised semiconductor regions 42 are formed on either side of the spacers 33 by epitaxy on the surface semiconductor layer 12.

Then, the amorphisation of the regions 42 and of the portions of the surface semiconductor layer 12a is carried out (FIG. 4D) and subsequently a doping of these regions 42 is performed (FIG. 4E). These amorphisation and doping steps may, again, as a variant be combined and carried out in a single implantation.

Subsequently, the recrystallisation and the activation of dopants by laser L annealing, in particular a nanosecond laser, is performed and preferably by implementing the explosive recrystallisation mode as described above (FIG. 4F).

According to another alternative example of method described above, the doping implantation(s) of the surface semiconductor layer 12 is(are) performed and that aims to perform a doping of extension areas 122 this time by doping and concomitantly making amorphous an upper part 123 of the surface semiconductor layer.

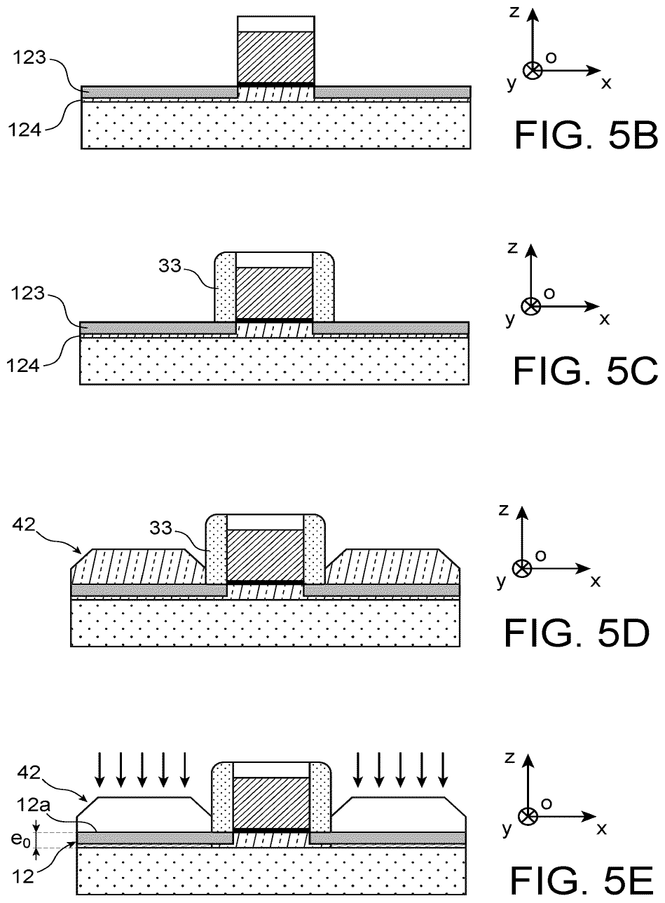

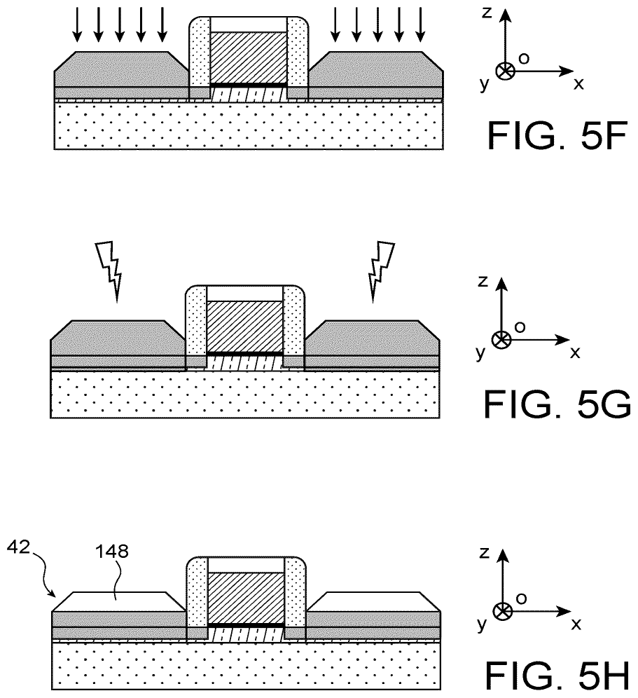

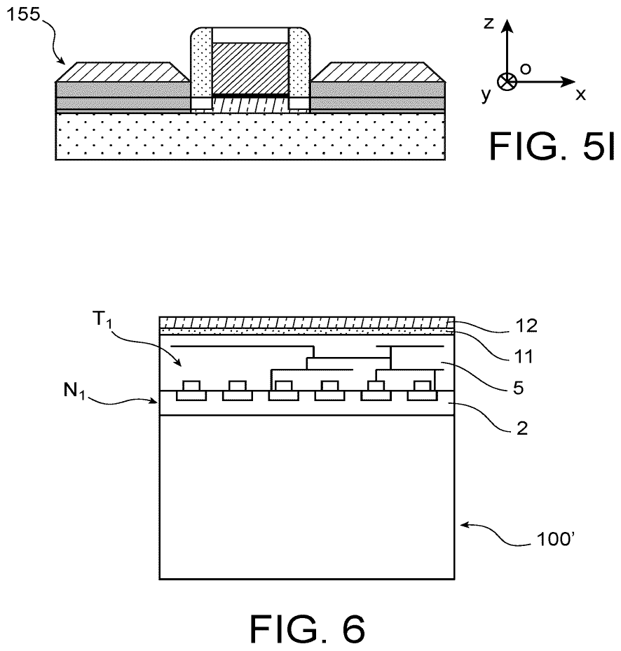

In this case, preferably a crystalline and non-amorphised lower area 124 of the surface semiconductor layer 12 is preserved under this upper part 123 made amorphous and doped. In the particular example of embodiment illustrated in FIG. 5A, this step is carried out before forming the spacers.

The preserved crystalline area 124 may have a thickness e₁₂₄ for example between 2 and 10 nm for a semiconductor layer of thickness between 5 and 30 nm.

Once the implantation of the dopants has been carried out, at least one thermal treatment is performed so as to carry out a recrystallisation annealing of the upper part 123 (FIG. 5B).

The lower area 124 is then used as a starting area for a recrystallisation front. A Solid Phase Epitaxial Regrowth (SPER) method of the amorphous semiconductor material in contact with the crystalline semiconductor material is in particular carried out at a temperature preferably less than 500° C. and that may be for example between 400° C. and 500° C.

Then (FIG. 5C), the spacers 33 are formed, for example by depositing a layer for example of thickness between 1 and 10 nm of silicon nitride then etching. Raised semiconductor regions 42 (FIG. 5D) are subsequently formed by epitaxy.

Subsequently, a complete amorphisation (FIG. 5E) is performed by implantation of these regions 42 and of the portions 12a of the surface semiconductor layer 12 arranged on either side of the spacers 33 and that extend over the entire thickness e0 of this surface layer 12 until reaching the underlying insulating layer 10.

Subsequently (FIG. 5F), a doping implantation can be carried out so as to perform a doping preferably over the entire thickness of the regions 42 and of the portions 12a of the surface semiconductor layer 12.

Then, a recrystallisation and an activation of dopants by exposure to a laser L is performed as described above, in particular using a nanosecond laser and typically in such a way as to transform into polycrystalline material, in particular polysilicon, the raised regions 42 as well as the portions 12a of the surface semiconductor layer 12 (FIG. 5G).

According to optional steps, it is subsequently possible to again perform an amorphisation (FIG. 5H) this time of an upper part 148 of the raised semiconductor regions 42. This amorphisation is implemented using an implantation that may possibly be implemented using a doping species.

Then (FIG. 5I), semiconductor and metal alloy areas 155 are formed, in particular in the upper part 148 of the raised semiconductor regions 42. For this, a metal, for example nickel or a nickel and platinum alloy, deposition then annealing is carried out, for example at a temperature between 200 and 400° C.

According to an alternative embodiment, it can be envisaged to implement a method such as described above on a support other than the substrate described above.

In particular, the starting structure of the method may be such that in the particular example of embodiment in FIG. 6, where the surface semiconductor layer 12 and the insulating layer 11 here rest on a support 100′ already including a first level N₁ of components, for example transistors.

Thus, one or more transistors T₁ of a first level N₁ of components are, in the example of embodiment illustrated, formed partly in an underlying semiconductor layer 2.

The transistors T₁ of the first level N₁ are covered by one or more metal interconnection stages formed in one or more insulating layers, typically a stack 5 of insulating layers, for example made of SiO₂. The stack 5 of insulating layers is provided or covered with the BOX insulating layer 11, this insulating layer 11 itself being covered with the surface semiconductor layer 12.

The method previously described may then be applied in order to produce one or more transistors of a second level. An activation and recrystallisation annealing with the nanosecond laser as described above and in particular adapted to perform a recrystallisation in explosive mode as mentioned above is then particularly adapted to this type of structure. In particular, it makes it possible to perform a doping of the source and drain regions of transistors of the second level without affecting and risking damage to the components of the first level.

1. A method for producing a transistor comprising the following steps of:
providing on a support provided with a surface semiconductor layer and resting on an insulating layer: at least one transistor gate block arranged on the surface layer, insulating spacers surrounding said gate block, and raised semiconductor regions resting on the surface semiconductor layer on either side of said gate block and insulating spacers,
making amorphous the raised semiconductor regions and the portions of the surface semiconductor layer located under these raised semiconductor regions over the entire thickness of said raised semiconductor regions and said portions, so as to reach the insulating layer,
doping the raised semiconductor regions and said portions,
carrying out at least one laser thermal annealing by means of one or more laser pulses so as to perform a recrystallisation of said raised regions and of said portions while carrying out an activation of dopants in said regions and said portions.

2. The method according to claim 1, wherein the step of making amorphous said raised semiconductor regions and said portions is carried out by implantation using a beam inclined in relation to a normal to a main plane of the support, so as to produce an amorphisation of areas of the surface layer that extend under the spacers (33).

3. The method according to claim 1, wherein the step of doping said raised semiconductor regions and said portions comprises an implantation using a beam inclined in relation to a normal to a main plane of the support, so as to dope the areas of the surface layer that extend under the spacers.

4. The method according to claim 1, further comprising the steps of:
forming the gate block,
forming spacers on either side of the gate block,
forming said raised semiconductor regions on either side of the spacers, the method further comprising after forming the gate block and before forming the spacers:
doping so-called extension areas of the surface semiconductor layer located on either side of the gate block, the spacers being formed facing said extension areas.

5. The method according to claim 4, wherein doping the extension areas in the surface semiconductor layer on either side of the gate block comprises steps of:
making amorphous and doping an upper part of the surface layer while keeping a crystalline lower layer of the surface layer in contact with the insulating layer,
carrying out an annealing so as to recrystallise said upper part of the surface layer.

6. The method according to claim 5, wherein after forming the insulating spacers and before amorphising said raised semiconductor regions and portions of the surface semiconductor layer located under these semiconductor regions:
forming by epitaxy the raised semiconductor regions on said recrystallised upper part of said surface layer.

7. The method according to claim 1, wherein after laser thermal annealing regions based on metal material and semiconductor material compounds are formed in the raised semiconductor regions.

8. The method according to claim 7, wherein before said laser thermal annealing at least one metal material layer is deposited so as to cover the raised semiconductor regions, the laser thermal annealing being adapted to form the regions based on metal material and semiconductor material compounds in the raised semiconductor regions.

9. The method according to claim 7, wherein after said laser thermal annealing, the method comprises steps of:
making amorphous the upper parts of said raised semiconductor regions, then
depositing at least one metal material layer so as to cover said raised semiconductor regions and carry out an annealing to form regions based on metal material and semiconductor material compounds in said upper parts.

10. The method according to claim 1, wherein the step of laser thermal annealing is carried out using a laser by emitting one or more successive laser pulses, of pulse duration less than a microsecond and preferably between 1 ns and 1,000 ns, advantageously between 20 ns and 300 ns, the laser having a wavelength between 200 nm and 600 nm and advantageously between 200 and 400 nm.

11. The method according to claim 1, wherein the laser thermal annealing is carried out so as to recrystallise said raised semiconductor regions and said portions of the surface semiconductor layer made amorphous in a recrystallisation mode wherein the raised semiconductor regions and said portions are transformed into polycrystalline material.

12. The method according to claim 1, wherein the support is a substrate of semiconductor on insulator type such as a SOI substrate or a support provided with one or more components of a first level of components formed in an underlying semiconductor layer.

13. The method according to claim 1, said portions of the surface semiconductor layer located under these raised semiconductor regions corresponding to parts of the surface semiconductor layer not covered by the gate block and extending over the entire thickness of the surface semiconductor layer.

14. The method according to claim 1, the step of making amorphous the raised semiconductor regions and the portions of the surface semiconductor layer being carried out so as not to keep any crystalline seed in the surface layer outside of an area facing the gate block.
